(19) United States
(12) Patent Application Publication
(10) Pub. No.: US 2025/0022908 A1
(43) Pub. Date: Jan. 16, 2025

(54) MICRO LIGHT EMITTING DIODE STRUCTURES FORMED IN A RECESS OF A TRANSPARENT SUBSTRATE

(71) Applicant: Intel Corporation, Santa Clara, CA (US)

(72) Inventors: Brandon Marin, Gilbert, AZ (US); Khaled Ahmed, San Jose, CA (US); Srinivas Pietambaram, Chandler, AZ (US); Gang Duan, Chandler, AZ (US)

(73) Assignee: Intel Corporation, Santa Clara, CA (US)

(21) Appl. No.: 18/221,601

(22) Filed: Jul. 13, 2023

(51) Int. Cl. H01L 27/15

(52) U.S. Cl. CPC H01L 27/156

(57) ABSTRACT

Techniques and mechanisms for a micro-LED (or “uLED”) device to facilitate communication of an optical signal which is propagated via a transparent substrate structure. In an embodiment, one or more recess structures are formed in a side of a transparent substrate structure, such as a glass core of a package substrate. A uLED structure extends partially through the transparent substrate structure in a first recess structure, and is oriented to transmit or receive an optical signal via the transparent substrate. In another embodiment, the uLED structure is coupled to integrated circuitry which provides functionality to operate the uLED structure, at different times, in either one of an optical signal receiver mode or an optical signal transmitter mode.

### CLAIM OF PRIORITY

The present application claims priority under 35 U.S.C. § 119 (e) to U.S. Provisional Patent Application Ser. No. 63/393,769 filed Jul. 29, 2022 and entitled “DEVICE, METHOD AND SYSTEM TO FACILITATE OPTICAL COUPLING WITH MICRO-LEDS,” which is herein incorporated by reference in its entirety.

### BACKGROUND

### 1. Technical Field

This disclosure generally relates to optical communication devices and more particularly, but not exclusively, to micro light emitting diode structures.

### 2. Background Art

Micro light emitting diodes (“micro-LEDs,” “uLEDs” or “uLEDs”) have great potential in the electronics industry due to the efficiency of their power performance. MicroLEDs have had wide use in various display applications, for example.

Increasing electrical domain data rates with serializer-deserializer (SerDes) technologies are problematic in advanced platforms. Placing the mixed-signal logic which is optimal for high signal rate communications is too costly in cutting edge logic nodes and is instead moved to special nodes and multi-chip strategies are used. This in turn drives yield problems and costs to increase. Power efficiency in SerDes paths is no longer scaling well and is expected to flatten at around 4 pJ/b sustained for short-reach (<0.3 m) communications in the electrical domain.

Traditional approaches to the I/O bandwidth problem in the electrical domain are to drive higher speed electrical signals (16→32→64→112→224 GHZ) with more complex encoding schemes (NRZ→PAM4) and bit error rate (BER) compensation mechanisms (CRC→FEC). In the optical domain, various technologies are being developed to provide multi-lambda encoding per optical fiber technique, with multiple fibers in parallel. Each lambda is encoded after a higher data rate electrical serializer-deserializer (SerDes) is used.

Currently, laser-based photonics are a leading candidate technology for long distance communication, such as from rack to rack in data centers, or from chip to chip. In this case, an external laser pumps light into a silicon photonics chip that takes an electrical signal from integrated circuit and produces light signals to transmit data to other chips via optical fibers. This approach brings cooling, complexity, power, and cost challenges.

Traditionally, standard laser-based silicon photonics have presented challenges in cooling and require exotic materials that are hard to reduce in cost. The physical area for laser-based photonics is also relatively large when compared to other technologies, as the laser modules and optical waveguides combined with micro-ring macros can easily require ˜100 square millimeters (mm²) per 1 terabyte per second (TB/s) transported.

Work on achieving longer range (e.g., 1 meter to 3 meter) communications with uLEDs has generally been directed at developing higher-power devices, lower loss optical media, or other improvements to fundamental materials. This work has been associated with higher cost pressures and longer timeline to production readiness.

Data communications are expected to grow beyond 150 zettabyte per year (ZB/year) in 2025. Accordingly, there are expected to be increasing data network demands at all link scales, including chip-to-chip, board-to-board, and rack-to-rack. Moreover, interconnect power now dominates and limits compute and artificial intelligence (AI) systems, requiring 10-100× more energy efficient solutions. Finally, cost of single-mode optical interconnect is currently greater than 10-100× higher than desired, and in general, it is well suited for off-the-package and longer reach (greater than 10 m) applications. On the technology front, recent years have witnessed a significant advancement of micro light emitters, which presents opportunities for the development of technologies to transfer such emitters from a source wafer to a host compute (XPU) wafer. This enables the formation of heterogeneous systems which bring optics and electronics closer to improve energy efficiency by greater than 10×. This technological trend provides significant tail winds for building parallel optical I/O (OIO) links. The parallelism will match the parallel nature of the XPU on-die fabrics and will minimize energy consumed in serializing and deserializing data in and out of the XPU. Such parallel systems augment traditional low-radix photonics to address challenges for high-radix network topologies at smaller than 2 meter distances, for example.

### BRIEF DESCRIPTION OF THE DRAWINGS

The various embodiments of the present invention are illustrated by way of example, and not by way of limitation, in the figures of the accompanying drawings and in which:

FIG. 1 shows a cross-sectional side view diagram illustrating features of a system to communicate an optical signal in uLED via a transparent substrate according to an embodiment.

FIG. 2 shows a flow diagram illustrating features of a method to provide uLED functionality according to an embodiment.

FIG. 3 shows a cross-sectional side view diagram illustrating features of a device to communicate an optical signal according to an embodiment.

FIG. 4 shows a perspective view diagram illustrating features of a device to provide an array of uLED structures according to an embodiment.

FIGS. 5A through 5H show cross-sectional side views of structures each during a respective stage of processing to fabricate uLED structures in recesses formed by a transparent substrate according to an embodiment.

FIGS. 6A, 6B show perspective views of structures each during a respective stage of processing to assemble a assemble an array of uLED structures according to an embodiment.

FIG. 7 shows a cross-sectional side view diagram illustrating features of a device comprising an array of lensed uLED structures according to an embodiment.

FIG. 8 shows a cross-sectional side view diagram illustrating features of a system to communicate an optical signal via a transparent substrate according to an embodiment.

FIG. 9 is a functional block diagram illustrating a computing device in accordance with one embodiment.

FIG. 10 is a functional block diagram illustrating an exemplary computer system, in accordance with one embodiment.

FIG. 11 is a cross-sectional view of an interposer implementing one or more embodiments.

### DETAILED DESCRIPTION

Embodiments discussed herein variously provide techniques and mechanisms for a micro-LED (or “uLED”) to communicate an optical signal which is propagated via a transparent substrate that structurally supports the micro-LED. In various embodiments, one or more recess structures are formed in a side of a transparent substrate that (for example) functions as a core of an interposer, a package substrate or the like. The one or more recess structures extend from one side of the transparent substrate, and only partially through the transparent substrate toward an opposite side thereof.

In this particular context, “micro-LED structure,” “uLED structure,” “uLED structure” and related terms variously refer to structures of a device (referred to herein “micro-LED device.” “uLED device.” or “uLED device” herein) which supports communication of an optical signal. For example, in some embodiments, such a device is able to be biased and/or otherwise configured to operate as an optical emitter device. However, in various embodiments, said device is additionally or alternatively able to be biased and/or otherwise configured to operate as an optical receiver device. To illustrate certain features of various embodiments, some uLED structures are described herein with respect to operations as an optical receiver. However, it is to be appreciated that such uLED structures additionally or alternatively operate as an optical transmitter, in some embodiments.

In one such embodiment, one or more uLEDs variously extend, at least in part, each in a respective recess structure formed by the transparent substrate. By way of illustration and not limitation, a uLED structure comprises a first doped portion, a second doped portion, and a quantum well structure which is disposed between the first doped portion and the second doped portion—e.g., wherein a first dopant type of the first doped portion is different than a second dopant type of the second doped portion. Some or all of the first doped portion, the second doped portion and the quantum well structure variously extend at least in part in a recess structure. In one such embodiment, the uLED structure is oriented to communicate—e.g., receive and/or transmit—optical signals which propagate through a bottom of such a recess structure. In providing uLED structures which extend partially in, and which communicate optical signals via, an underlying transparent substrate, some embodiments variously enable new optical communication paths which (for example) are relatively space efficient and/or cost efficient.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including a transparent substrate and one or more uLEDs which extend at least in part in said transparent substrate.

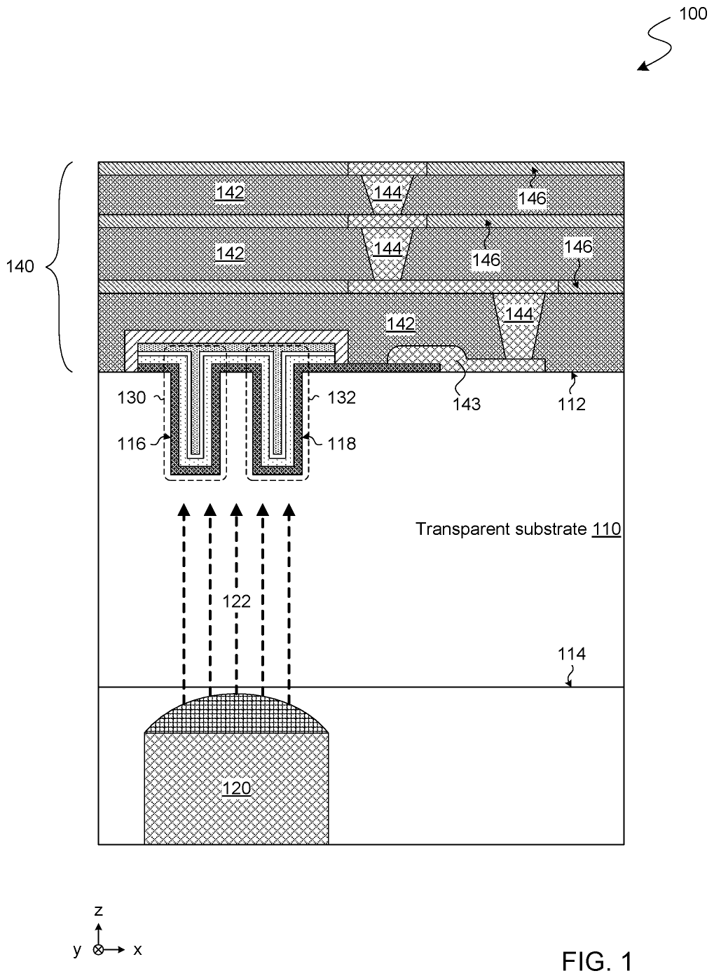

FIG. 1 shows a cross-sectional side view of a system 100 which includes at least one uLED structure which is formed in a transparent substrate according to an embodiment. System 100 illustrates one example embodiment wherein one or more recess structures are formed in a side of a transparent substrate, wherein one or more uLEDs each extend at least partially in a respective one of the one or more recess structures. In an embodiment, the one or more uLEDs are configured to communicate an optical signal which is propagated in an amorphous material of the transparent substrate.

Structures of system 100 are shown with reference to an xyz Cartesian coordinate system. Unless otherwise indicated, “length” refers herein to a dimension along the x-axis of the coordinate system, wherein “width” and “height” refer to dimension along the y-axis and the z-axis (respectively) of the coordinate system.

As shown in FIG. 1, system 100 comprises a transparent substrate structure 110 and a substrate structure 140 which is coupled to transparent substrate structure 110. In various embodiments, transparent substrate structure 110 comprises any of various materials which are suitable to accommodate a propagation of an optical signal therein. In one such embodiment, transparent substrate structure 110 comprises an amorphous layer of an optically transparent material. For example, the transparent material forms an amorphous solid glass layer—e.g., wherein the transparent material is a glass comprising one or more of aluminosilicate, borosilicate, alumino-borosilicate, silica, and fused silica. In one such embodiment, the glass further comprises one or more additives including, but not limited to, one of Al₂O₃, B₂O₃, MgO, CaO, SrO, BaO, SnO₂, Na₂O, K₂O, SrO, P₂O₃, ZrO₂, Li₂O, Ti, or Zn. By way of illustration and not limitation, in some embodiments, the glass comprises silicon and oxygen, as well as any one or more of aluminum, boron, magnesium, calcium, barium, tin, sodium, potassium, strontium, phosphorus, zirconium, lithium, titanium, or zinc. In one such embodiment, transparent substrate structure 110 comprises silicon, oxygen, and aluminum—e.g., wherein transparent substrate structure 110 comprises at least 23 percent silicon and at least 26 percent oxygen by weight, and further comprises at least 5 percent aluminum by weight. In various embodiments, an amorphous solid glass layer of transparent substrate structure 110 omits an organic adhesive (or any other organic material, in some embodiments).

In some embodiments, transparent substrate structure 110 is a solid layer of a glass material which, in the horizontal (x-y) plane, is substantially rectangular in shape. In an illustrative scenario according to one embodiment, an overall (z-axis) thickness of transparent substrate structure 110 is in a range of 50 micrometers (um) to 2000 um—e.g., wherein an overall (x-axis) length of transparent substrate structure 110 is in a range of 5 millimeters (mm) to 200 mm, and wherein an overall (y-axis) width of transparent substrate structure 110 is in a range of 5 to 200 mm.

Substrate structure 140 illustrates any of various types of components which are structurally supported by (and/or which provide structural support for) transparent substrate structure 110. In an embodiment, substrate structure 140 comprises circuit structures which support the performance of electrical signaling and/or other operations with uLED structures that extend in transparent substrate structure 110. In various embodiments, substrate structure 140 includes at least part of any suitable substrate such as that of a circuit board, an interposer, a die, or a package substrate (for example)—e.g., wherein substrate structure 140 includes any suitable material such as a ceramic, silicon, or dielectric.

In some embodiments, substrate structure 140 is a circuit board, for example, a printed circuit board (PCB) including multiple metal layers separated from one another by layers of dielectric material and interconnected by electrically conductive vias. In other embodiments, the circuit board is a non-PCB substrate. In some embodiments, substrate structure 140 is at least part of a package substrate including an insulating material (e.g., a dielectric material formed in multiple layers, as known in the art) and one or more conductive pathways through the dielectric material (e.g., including conductive traces and/or conductive vias). A dielectric layer includes a single layer or includes multiple layers, for example. In some embodiments, the insulating material of the package substrate is a dielectric material, such as an organic dielectric material, a fire retardant grade 4 material (FR-4), BT resin, polyamide materials, glass reinforced epoxy matrix materials, or low-k and ultra low-k dielectric (e.g., carbon-doped dielectrics, fluorine-doped dielectrics, porous dielectrics, and organic polymeric dielectrics). In some embodiments, the conductive pathways in the package substrate is bordered by liner materials, such as adhesion liners and/or barrier liners, as suitable. In some embodiments, the package substrate is coreless. In some embodiments, the package substrate includes a core or carrier—e.g., wherein transparent substrate structure 110 is the core of such a package substrate. For example, in one such embodiment, transparent substrate structure 110 is a core of a package substrate which includes substrate structure 140 at a surface 112 of transparent substrate structure 110, and another substrate structure (not shown) which adjoins transparent substrate structure 110 at an opposite surface 114 of transparent substrate structure 110. In some embodiments, substrate structure 140 is an interposer formed of an epoxy resin, a fiberglass-reinforced epoxy resin, an epoxy resin with inorganic fillers, a ceramic material, or a polymer material such as polyamide. In some embodiments, the interposer is formed of alternate rigid or flexible materials that includes the same materials described above for use in a semiconductor substrate, such as silicon, germanium, and other group III-V and group IV materials. In one such embodiment, insulation layers 142 include one or more layers of an inorganic inter-layer dielectric (ILD) material such as, but not limited to, any of various silicon oxides, carbon doped silicon oxides, silicon oxynitride, or silicon nitride—e.g., wherein insulation layers 142 of substrate structure 140 comprise a low-k dielectric material. Such an interposer includes metal interconnects and vias, including but not limited to through silicon vias (TSVs), for example.

In some embodiments, substrate structure 140 includes conductive pathways to route power, ground, and/or signals, or to electrically couple different components—e.g., to electrically couple a uLED structure to one or more active circuit elements (not shown) which substrate structure 140 includes or accommodates coupling to. In the example embodiment shown, substrate structure 140 comprises metallization layers 146 and insulation layers 142 which variously provide at least partial electrical insulation between respective ones of metallization layers 146. Metallization layers 146 comprise respective patterned interconnect structures, wherein via structures 144 variously extend each through a respective one of insulation layers 142. In one such embodiment, a given one of the via structures 144 electrically couples interconnect structures which are each in a different respective one of metallization layers 146. Any one or more of metallization layers 146 are formed in a desired circuit pattern, with some or all of via structures 144, to route electrical signals (optionally in conjunction with other metal layers) between components which are included in—or alternatively, coupled to—substrate structure 140. Some embodiments are not limited with respect to a particular functionality which is provided with said electrical signals and/or with said components.

In the example embodiment shown, one or more recess structures (e.g., including the illustrative recess structures 116, 118 shown) are variously formed by a surface 112 which is at a first side of transparent substrate structure 110. For example, portions of surface 112 extend along a horizontal (x-y) plane, wherein the one or more recess structures variously extend in a vertical (z-axis) direction from said horizontal plane toward another surface 114 which is formed at a second side of transparent substrate structure 110 (wherein the second side is opposite the first side). In an embodiment, recess structures 116, 118 each extend only partially through the height of transparent substrate structure 110.

To facilitate communication of one or more optical signals, system 100 further comprises one or more uLED devices, one or more structures of which each extend into a respective recess structure formed at surface 112. By way of illustration and not limitation, a first uLED structure 130 extends in recess structure 116, and (in some embodiments) a second uLED structure 132 extends in recess structure 118. The uLED structures 130, 132 are variously oriented each to receive and/or transmit a respective optical signal which is to propagate in transparent substrate structure 110.

In various embodiments, a given one such uLED structure—e.g., uLED structure 130—comprises doped portions (each of a respective wide band gap material), and a relatively narrow band gap quantum well structure which extends between said doped portions. Some or all of the doped portions and the quantum well structure extend at least partially into the recess structure. In one such embodiment, the given uLED structure further comprises a transparent electrode structure which extends at least partially into the recess structure—e.g., wherein the transparent electrode structure extends around the first doped portion, the second doped portion, and the quantum well structure.

In various embodiments, two or more such uLED structures, which extend in different respective recess structures, are formed at least in part by the same one or more contiguous bodies of respective semiconductor materials. By way of illustration and not limitation, a single uLED device comprises both uLED structure 130 and uLED structure 132, which operate in combination with each other to communicate (e.g., sense or emit) the same optical signal. In an alternate embodiment, uLED structures 130, 132 are instead structures of different respective uLED devices which (for example) are to communicate different respective optical signals.

In an embodiment, a given one (or both) of uLED structures 130, 132 is coupled to communicate an electrical signal with integrated circuitry (not shown) that system 100 includes or, alternatively, accommodates coupling to. For example, uLED structures 130, 132 provide functionality to generate the electrical signal based on a received optical signal. Additionally or alternatively, uLED structures 130, 132 provide functionality to generate and emit an optical signal based on an electrical signal.

By way of illustration and not limitation, system 100 further comprises an interconnect structure 143 at surface 312, wherein interconnect structure 143 couples one or both of the uLED structures 130, 132 to other circuit structures such as ones of insulation layers 142 and metallization layers 146. With such interconnect structures, integrated circuitry (not shown) is able to bias or otherwise configure one or both of uLED structures 130, 132 to operate as an optical receiver device or, alternatively, as an optical transmitter device.

In the example embodiment shown, system 100 further comprises (or alternatively, accommodates optical coupling to) an optical communication device 120. In one such embodiment, an optical signal 122 is communicated from optical communication device 120 to one or both of uLED structures 130, 132—e.g., wherein optical signal 122 propagates from surface 114, and through transparent substrate structure 110, to the bottom of one or both of recess structures 116, 118. For example, optical communication device 120 includes any of various suitable optical transmitters, such as a vertical-cavity surface-emitting laser (VCSEL), a Fabry-Perot (FP) laser, a distributed feedback (DFB) laser, a light emitting diode (LED), a resonant cavity light emitting diode (RCLED), or the like. In an embodiment, interconnect structure 143 facilitates communication of an electrical signal which is generated with uLED structures 130, 132 based on optical signal 122.

In an alternate embodiment, optical signal 122 is instead communicated from one or both of uLED structures 130, 132 to optical communication device 120—e.g., wherein optical signal 122 propagates from the bottom of one or both of recess structures 116, 118, and through transparent substrate structure 110, to surface 114. For example, optical communication device 120 additionally or alternatively comprises any of various optical receiver devices, such as, for example, a photo intrinsic (PIN) diode, an avalanche photo diode (APD), or the like. In one such embodiment, interconnect structure 143 facilitates communication of an electrical signal with one or both of uLED structures 130, 132—e.g., wherein optical signal 122 (or another optical signal) is output by uLED structures 130, 132 based on the electrical signal.

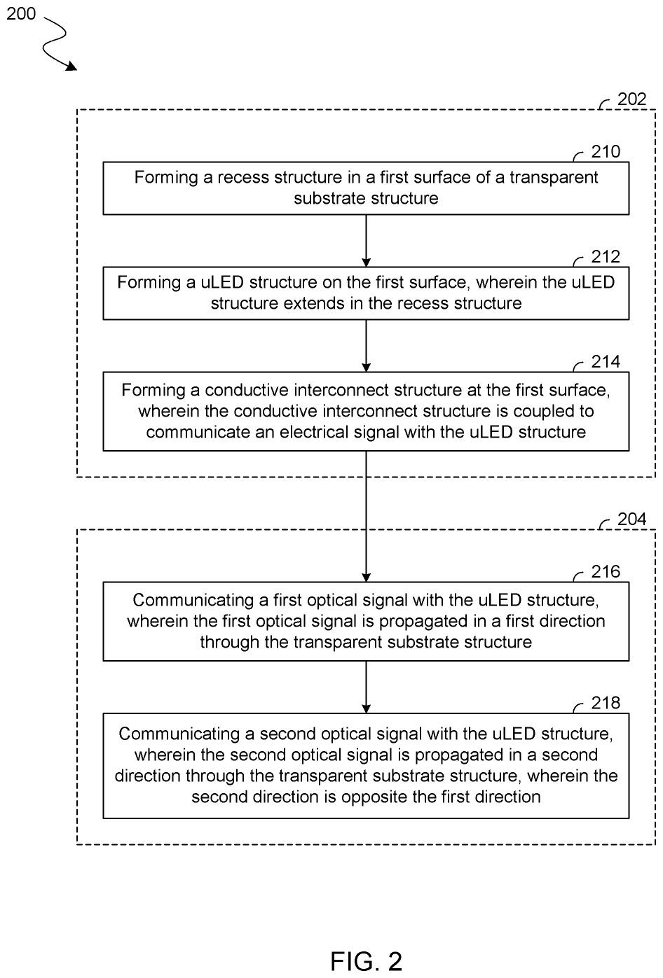

FIG. 2 shows a method 200 for providing uLED functionality according to an embodiment. Operations such as those of method 200 are performed, for example, to provide and/or use optical communication structures such as those provided with system 100.

In some embodiments, method 200 comprises operations 202 for fabricating, assembling and/or otherwise providing one or more uLEDs, structures which variously extend each into a respective recess that is formed in a transparent substrate. For example, as shown in FIG. 2, operations 202 comprise (at 210) forming a recess structure in a first surface of a transparent substrate structure (such as surface 112 of transparent substrate structure 110). In various embodiments, the first surface extends in a first horizontal (x-y) plane at a first side of the transparent substrate structure—e.g., wherein the recess structure extends in a horizontal (z-axis) direction from the first plane toward a second, opposite side of the transparent substrate structure. In an embodiment, the transparent substrate structure is a glass core of a package substrate (for example).

Operations 202 further comprise (at 212) forming a uLED structure on the first surface, wherein the uLED structure extends in the recess structure. In an embodiment, the uLED structure is oriented to communicate an optical signal which is propagated through the transparent substrate structure. In various embodiments, forming the uLED structure at 212 comprises forming a first doped portion, a second doped portion, and quantum well structure which extends between the first doped portion and the second doped portion. For example, the doped portions and the quantum well structure are variously formed using patterned mask, lithographic etch, deposition and/or other suitable operations that, for example, are adapted from conventional semiconductor fabrication techniques. After the uLED structure is formed at the first surface, one or more of the first doped portion, the second doped portion, or the quantum well structure extend at least partially into the recess structure.

By way of illustration and not limitation, the forming at 212 comprises performing a first deposition of a first doped, wide bandgap material (such as p-type GaN) into the recess structure. Furthermore, the forming at 212 comprises, after the first deposition, performing a second deposition of an undoped, relatively narrow band gap material (such as InGaN) into the recess structure—e.g., wherein a layer of the undoped material is formed on a layer of the first doped material. After the second deposition, the forming at 212 performs a third deposition of a second doped, wide bandgap material (such as n-type GaN) into the recess structure—e.g., wherein a layer of the second doped material is formed on the layer of the undoped material. In an alternative embodiment, the forming at 212 comprises fabricating the uLED structure outside of the recess structure (and separate from the transparent substrate, for example), and subsequently performing an assembly which inserts at least a portion of the uLED structure into the recess structure.

In some embodiments, forming the recess structure at 210 comprises forming multiple recess structures that each extend in the first surface—e.g., wherein forming the uLED structure at 212 comprises forming multiple uLED structures which each extend into a different respective one of the multiple recess structures. In one such embodiment, one or more layers and/or other contiguous bodies (each of a respective semiconductor material) variously form, in some or all of the recess structures, respective portions of a plurality of such uLED structures. By way of illustration and not limitation, a first layer of a first doped, wide band gap material forms respective first doped portions of a first uLED structure and a second uLED structure. Furthermore, a second layer of an undoped material forms respective quantum well structures of the first uLED structure and the second uLED structure. Further still, a contiguous body of a second doped material forms respective second doped portions of the first uLED structure and the second uLED structure.

Referring again to FIG. 2, operations 202 further comprise (at 214) forming a conductive interconnect structure (such as interconnect structure 143) at the first surface, wherein the conductive interconnect structure is coupled to communicate an electrical signal with the uLED structure (and, for example, with any of various suitable receiver driver circuits and/or transmit driver circuits). In one embodiment, the uLED is oriented to communicate an optical signal via the transparent substrate—e.g., wherein the electrical signal is generated with the uLED structure based on the optical signal, or (alternatively), wherein the optical signal is emitted with the uLED structure based on the electrical signal.

For example, in various embodiments, method 200 additionally or alternatively comprises operations 204 for performing communications with uLED structures such as those provided by operations 202. In one such embodiment, operations 204 comprise (at 216) communicating a first optical signal with the uLED structure, wherein the first optical signal is propagated in a first direction in the transparent substrate structure. In the example embodiment of system 100, the communicating at 216 comprises uLED structure 130 and/or uLED structure 132 receiving an optical signal 122 which propagates within transparent substrate structure 110 in a direction away from surface 314 and toward surface 312—e.g., wherein, based on optical communication device 120, uLED structure 130 and/or uLED structure 132 generate an electrical signal which is then communicated via interconnect structure 143.

Additionally or alternatively, operations 204 comprise (at 218) communicating a second optical signal with the uLED structure, wherein the second optical signal is propagated in the transparent substrate structure in a second direction which is opposite the first direction. For example, the communicating at 218 comprises uLED structure 130 and/or uLED structure 132 emitting an optical signal based at least in part on an electrical signal which is received via interconnect structure 143, wherein the optical signal propagates within transparent substrate structure 110 in a direction away from surface 312 and toward surface 314.

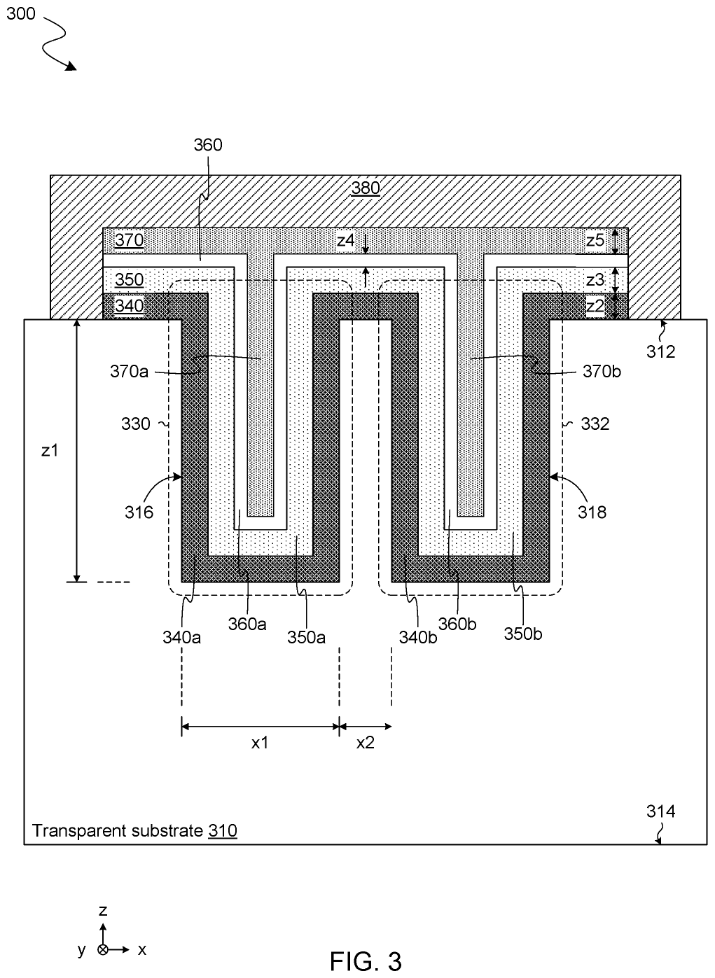

FIG. 3 shows a cross-sectional side view of a device 300 for communicating an optical signal according to an embodiment. Device 300 illustrates features of one example embodiment wherein structures of a uLED extend in a recess of a transparent substrate, where said structures comprise doped portions and a quantum well material between said doped portions. In some embodiments, device 300 provides functionality similar to a functionality of system 100—e.g., wherein operations of method 200 use and/or provide structures of device 300.

As shown in FIG. 3, device 300 comprises a transparent substrate 310 and uLED structures 330, 332 which extend in respective recess structures 316, 318 that are formed in a surface 312 of transparent substrate 310. Portions of surface 312 extends in a horizontal (x-y) plane, wherein recess structures 316, 318 extend from said horizontal plane in a vertical (z-axis) direction toward an opposite surface 314 of transparent substrate 310. In various embodiments, transparent substrate 310, and uLEDs 330, 332 correspond functionally to transparent substrate structure 110, and uLED structures 130, 132 (respectively).

Transparent substrate 310 comprises an amorphous layer of any of various suitable optically transparent materials. For example, the transparent material forms an amorphous solid glass layer—e.g., wherein the transparent material is a glass comprising one or more of aluminosilicate, borosilicate, alumino-borosilicate, silica, and fused silica. In one such embodiment, the glass further comprises one or more additives including, but not limited to, one of Al₂O₃, B₂O₃, MgO, CaO, SrO, BaO, SnO₂, Na₂O, K₂O, SrO, P₂O₃, ZrO₂, Li₂O, Ti, or Zn. By way of illustration and not limitation, in some embodiments, the glass comprises silicon and oxygen, as well as any one or more of aluminum, boron, magnesium, calcium, barium, tin, sodium, potassium, strontium, phosphorus, zirconium, lithium, titanium, or zinc.

In an embodiment, uLED structures 330, 332 are structures of a single uLED device, wherein layers and/or other contiguous bodies of respective materials each form respective portions of both uLED structure 330 and uLED structure 332. For example, such contiguous bodies comprise some or all of a transparent conductor structure 340, a doped structure 350, a quantum well structure 360, and another doped structure 370.

In the example embodiment shown, doped structure 370 is a contiguous body of a first doped, wide band-gap material which forms a core structure 370a extending in recess structure 316. Furthermore, quantum well structure 360 is a layer of a relatively narrow band-gap material which forms a shell structure 360a extending around core structure 370a in recess structure 316. Further still, doped structure 350 is a layer of a second doped, wide band-gap material which forms a shell structure 350a extending around shell structure 360a in recess structure 316. Although some embodiments are not limited in this regard, transparent conductor structure 340 forms another shell structure 340a extending around shell structure 350a in recess structure 316—e.g., wherein transparent conductor structure 340 extends to electrically couple an interconnect structure (such as interconnect structure 143) to the uLED device.

By way of illustration and not limitation, doped structure 370 comprises an n-type doped material comprising gallium and nitride—e.g., wherein a stoichiometry of the n-type doped material is substantially equal to a stoichiometry of a gallium nitride (GaN) compound. Furthermore, quantum well structure 360 comprises a conformal layer of a material comprising indium, gallium and nitride—e.g., wherein a stoichiometry of the p-type doped material is substantially equal to a stoichiometry of an indium gallium nitride (InGaN) compound. Further still, doped structure 350 comprises a conformal layer of a p-type doped material comprising gallium and nitride—e.g., wherein a stoichiometry of the p-type doped material is substantially equal to a stoichiometry of a gallium nitride (GaN) compound. In one such embodiment, transparent conductor structure 340 is a layer of indium tin oxide (ITO), gallium doped zinc oxide (GZO) or any of various other suitable materials.

Although some embodiments are not limited in this regard, doped structure 370 further forms another core structure 370b extending in recess structure 318—e.g., wherein quantum well structure 360 further forms another shell structure 360b extending around core structure 370b in recess structure 318, and wherein doped structure 350 further forms another shell structure 350b extending around shell structure 360b in recess structure 318. Although some embodiments are not limited in this regard, transparent conductor structure 340 further forms another shell structure 340b extending around shell structure 350b in recess structure 318. In various embodiments, device 300 further comprises an insulator structure 380—e.g., comprising any of various other suitable dielectric materials to provide at least partial electrical insulation between the uLED device and other circuit structures (not shown) that device 300 includes or accommodated coupling to. In one such embodiment, insulator structure 380 comprises silicon and nitrogen—e.g., wherein a stoichiometry of insulator structure 380 is substantially the same as a stoichiometry of any of various suitable SiN compounds.

In an illustrative scenario according to one embodiment, an overall thickness of transparent substrate 310 (between sides 312, 314) is in a range of 50 um to 2000 um—e.g., wherein a length (x-axis) of transparent substrate 310 is in a range of 5 mm to 200 mm, and/or wherein a width (y-axis) of transparent substrate 310 is in a range of 5 mm to 200 mm. In one such embodiment, a depth z1 of recess structure 316 (or of recess structure 318, for example) is in a range of 10 nm to 10000 nm—e.g., wherein a length x1 of recess structure 316 is in a range of 10 um to 500 um, and/or wherein a width (y-axis) of recess structure 316 is in a range of 10 nm to 10000 nm. Furthermore, a conformal (z-axis) thickness z2 of transparent conductor structure 340 is in a range of 1 nm to 500 nm—e.g., wherein a conformal thickness z3 of doped structure 350 is in a range of 1 nm to 500 nm, and wherein a conformal thickness z4 of quantum well structure 360 is in a range of 1 nm to 500 nm. Further still, a thickness 25 of doped structure 370 on surface 312 is in a range of 1 nm to 500 nm. However, structural dimensions of device 300 are merely illustrative of some embodiments, and other embodiments are not limited with respect to some or all such structural dimensions.

In an alternative embodiment, device 300 omits recess structure 318 and uLED structure 332, or (for example) uLED structures 330, 332 are instead structures of distinct uLED devices which are at least partially isolated electrically from each other—e.g., wherein the respective portions of structures 340, 350, 360, and 370 are instead absent at surface 312 in a region between recess structures 316, 318. In some embodiments, one or more uLED structures of device 300 include any of various additional or alternative features which, for example, are adapted from conventional uLED designs—e.g., wherein said one or more uLED structures comprise any of various other suitable doped wide band gap materials, comprise any of various other suitable narrow band gap quantum well materials, comprise multiple quantum well structures, and/or the like.

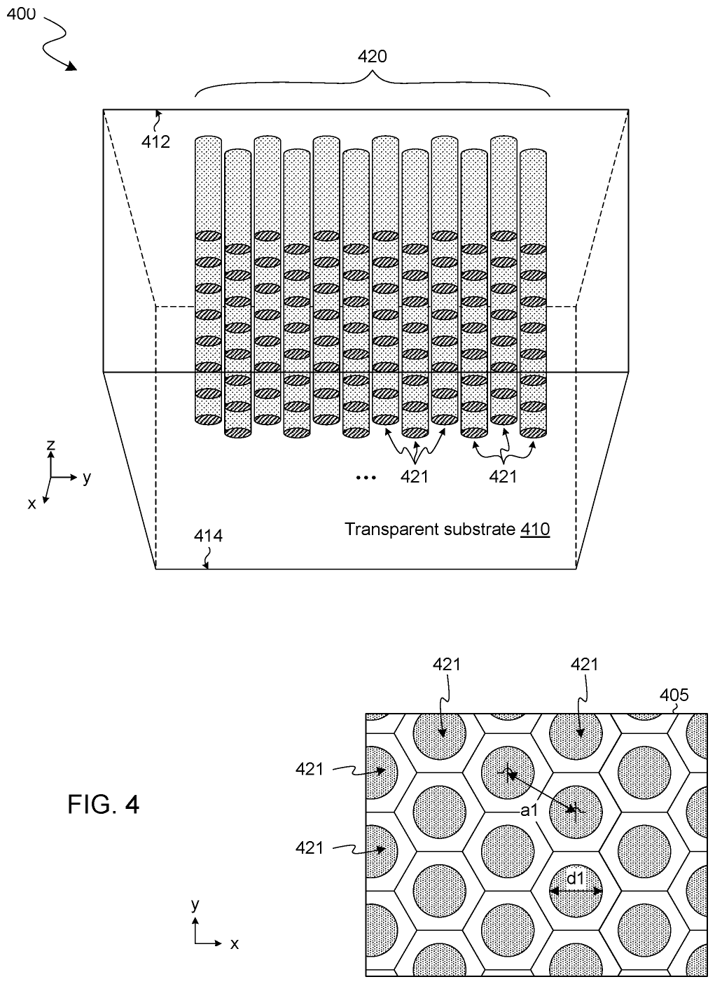

FIG. 4 shows a perspective view of a device 400 which comprises an array of uLED structures according to an embodiment. Device 400 illustrates features of one example embodiment wherein uLED structures each extend in a respective recess structure of a transparent substrate, wherein an arrangement of the uLED structures corresponds to an arrangement of polygonal tiles in a regular tessellation pattern. In some embodiments, device 400 provides functionality similar to that of system 100 or device 300—e.g., wherein operations of method 200 are to manufacture and/or use structures of device 400.

As shown in FIG. 4, device 400 comprises a transparent substrate 410 and an array 420 of uLED structures 421. A surface 412, at a first side of transparent substrate 410, has formed therein recess structures which variously extend in a vertical (z-axis) direction from surface 412 and toward another surface 414 at an opposite side of transparent substrate 410. The uLED structures 421 extend each in a different respective one of said recess structures—e.g., wherein the uLED structures 421 are each oriented to transmit or receive a respective optical signal via transparent substrate 410 (and the surface 414 thereof). In various embodiments, transparent substrate 410, and uLED structures 421 correspond functionally to transparent substrate structure 110 and uLED structures 130, 132, respectively (or to transparent substrate 310 and uLED structures 330, 332, respectively).

An inset 405 in FIG. 4 shows a detail view of a horizontal (x-y) cross-section of a part of array 420. As illustrated by inset 405, an arrangement of uLED structures 421 in array 420 conforms to an arrangement of polygonal (in this example embodiment, hexagonal) tiles in a regular tessellation pattern. In so arranging the uLED structures 421, some embodiments variously provide a photonic crystal structure that is able to produce a very narrow linewidth and very directional beam from array 420. In an illustrative scenario according to one embodiment, a horizontal length d1 (e.g., a diameter) of a given uLED structure 421 is in a range of 10 um to 500 um—e.g., wherein a distance al between neighboring uLED structures 421 is in a range of 12 um to 510 um.

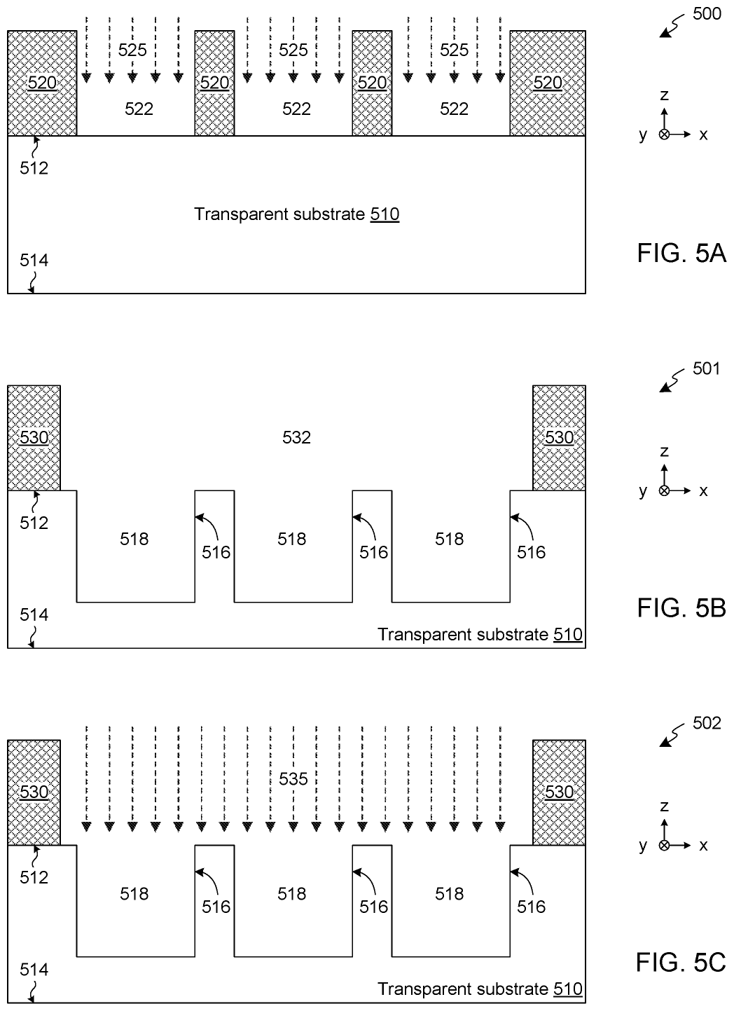

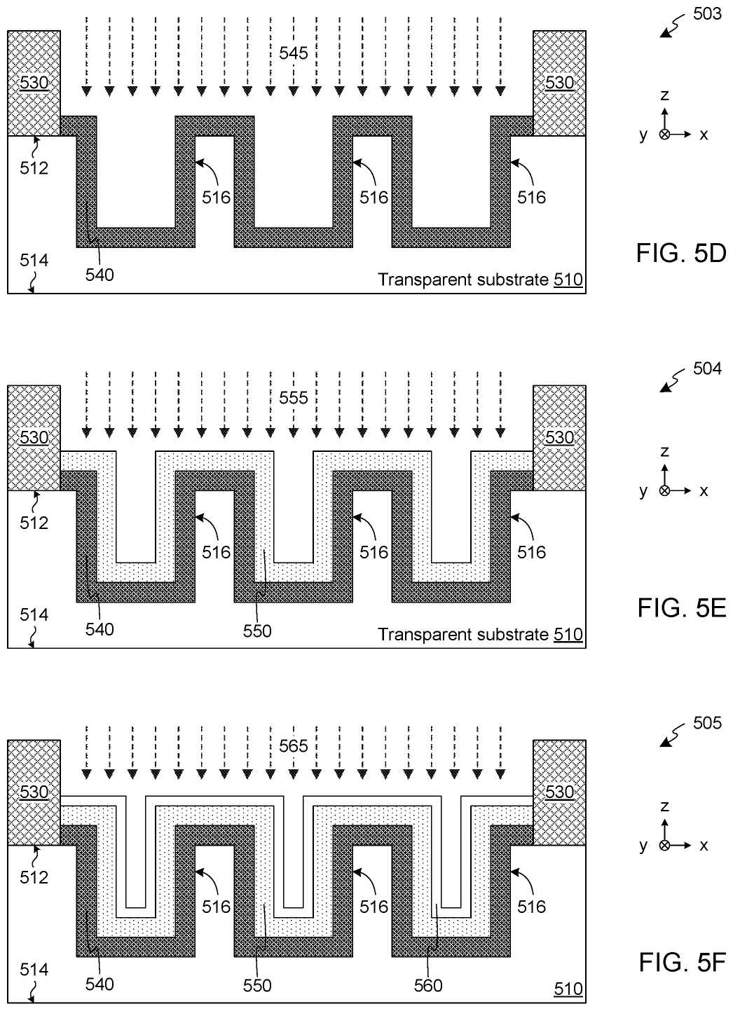

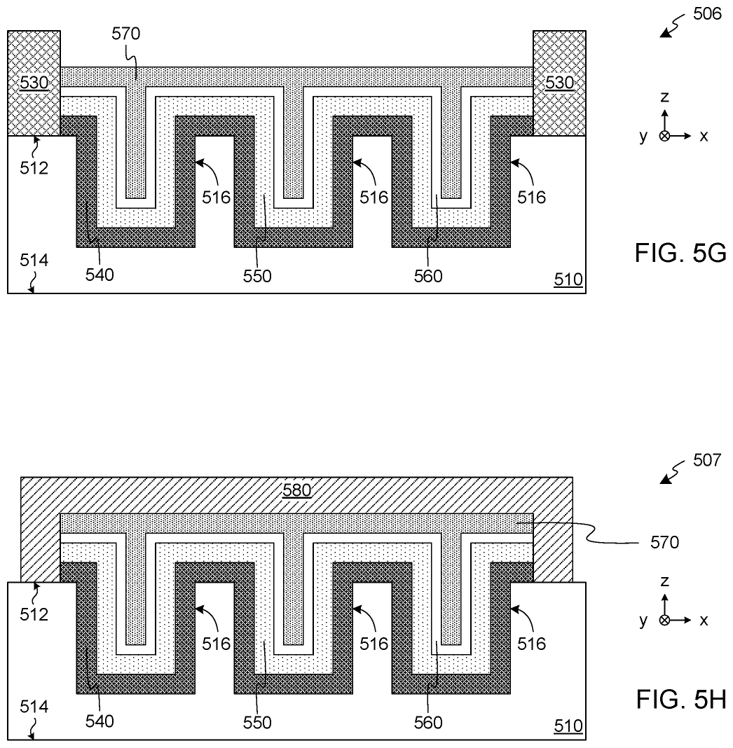

FIGS. 5A through 5H show various cross-sectional side views of structures each during a respective one of multiple stages 500 through 507 of processing to fabricate uLED structures in recesses which are formed in a transparent substrate according to an embodiment. In various embodiments, processing such as that illustrated by stages 500 through 507 provides structures of system 100, device 300, or device 400—e.g., wherein said processing includes operations of method 200.

As shown in FIG. 5A, any of various suitable deposition and lithographic patterning processes are performed to form a patterned mask 520 which, at stage 500, is on a surface 512 of a transparent substrate 510. In an embodiment, an amorphous glass material of transparent substrate 510 has properties such as those of a material of transparent substrate structure 110, transparent substrate 310, or transparent substrate 410, for example. Patterned mask 520 forms holes 522 which expose portions of surface 512 to an etch processing 525 which (for example) comprises any of various suitable wet etch or dry etch operations.

Referring now to FIG. 5B, etch processing 525 results in the formation of recess structures 516 which, at stage 501, extend in a vertical (z-axis) direction toward a surface 514 of stage 500 which is opposite surface 512. After the formation of recess structures 516, etch, grind, polish and/or other subtractive processing to remove patterned mask 520. Subsequently, additional deposition and lithographic patterning processing is performed to form another patterned mask 530 on the surface 512 of transparent substrate 510. Patterned mask 530 forms one or more holes (such as the illustrative hole 532 shown) which expose regions 518 within the respective recess structures 516.

At the stage 502 shown in FIG. 5C, regions 518 and other exposed regions of transparent substrate 510 are subjected to deposition processing 535 to deposit, through hole 532, any of various suitable transparent conductive materials including, but not limited to, ITO, GZO, or the like. By way of illustration and not limitation, deposition processing 535 comprises physical vapor deposition (PVD) or any of various other suitable processes.

As shown in FIG. 5D, the deposition processing 535 (e.g., PVD processing) results in the formation, at stage 503, of a transparent conductor structure 540 which (in this example) is a conformal layer that variously extends along the respective sidewalls and bottom surfaces of recess structures 516. After deposition processing 535, another deposition processing 545 is performed through hole 532 to deposit a first doped wide gap band material. In an illustrative scenario according to one embodiment, deposition processing 545 deposits a p-type doped material onto surfaces of transparent conductor structure 540—e.g., wherein a stoichiometry of the p-type doped material is substantially equal to a stoichiometry of a p-type doped gallium nitride (GaN) compound.

Referring now to FIG. 5E, deposition processing 545 (e.g., PVD processing) results in the formation, at stage 504, of a doped structure 550 which, for example, is a conformal layer that variously extends along the respective surfaces of transparent conductor structure 540 which are in recess structures 516. After deposition processing 545, another deposition processing 555 is performed through hole 532 to deposit an undoped, relatively narrow gap band material on doped structure 550. In various embodiments, deposition processing 555 deposits a material which has a stoichiometry that is substantially equal to a stoichiometry of an indium gallium nitride (InGaN) compound.

At the stage 505 shown in FIG. 5F. deposition processing 555 (e.g., PVD processing) has resulted in the formation of a quantum well structure 560 which, for example, is a conformal layer that variously extends along the respective surfaces of doped structure 550 which are in recess structures 516. After deposition processing 555, another deposition processing 565 is performed through hole 532 to deposit a second doped wide gap band material. In various embodiments, deposition processing 565 deposits an n-type doped material onto surfaces of quantum well structure 560—e.g., wherein a stoichiometry of the n-type doped material is substantially equal to a stoichiometry of an n-type doped gallium nitride (GaN) compound

As shown in FIG. 5G, deposition processing 565 (e.g., PVD processing) results in the formation, at stage 506, of a doped structure 570 which extends along the respective surfaces of quantum well structure 560 which are in recess structures 516—e.g., wherein doped structure 570 fills remaining portions of regions 518. In one such embodiment, doped structure 570 forms core structures which extend each in a different respective one of recess structures 516—e.g., wherein quantum well structure 560, doped structure 550, and transparent conductor structure 540 form in a given one of recess structures 516 respective shell structures which successively surround a corresponding one of the core structures.

Referring now to FIG. 5H, additional processing is performed to form an insulator structure 580 which, at stage 507, extends over the uLED structures which are variously formed in recess structures 516. For example, additional etch, grind, polish and/or other subtractive processing is performed to remove patterned mask 530—e.g., wherein further lithographic patterning and material deposition is performed to deposit a dielectric material (e.g., SiN) which provides at least partially electrical insulation of the underlying uLED device.

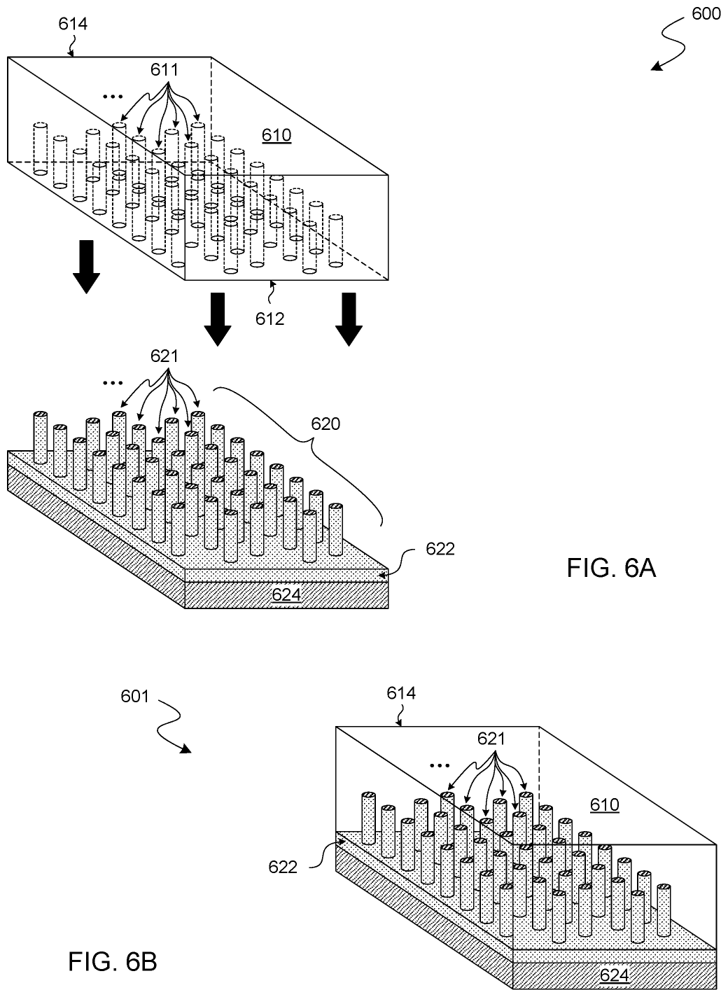

FIGS. 6A, 6B show various perspective views of structures each during a respective one of multiple stages 600, 601 of processing to assemble an array of uLED structures according to an embodiment. In various embodiments, processing such as that illustrated by stages 600, 601 provides structures of system 100, method 200, or device 400—e.g., wherein said processing includes operations of method 200.

As shown in FIG. 6A, a substrate structure 624 is brought into alignment, at stage 600, with a transparent substrate 610. Recess structures 611 are formed in a surface 612 which is at a first side of transparent substrate 610, wherein recess structures 611 extend partially through transparent substrate 610 toward a surface 614 at an opposite side thereof. Substrate structure 624 comprises an array 620 of uLED structures 621 which, for example, extend from an active layer 622. In an embodiment, active layer 622 includes at least a portion of some active circuit components including, for example, one or more uLED devices which further comprise some or all of uLED structures 621. In an illustrative scenario according to one embodiment, transparent substrate 610 provides functionality of transparent substrate structure 110, transparent substrate 310, or transparent substrate 410—e.g., wherein recess structures 611 comprise recess structures 116, 118 (for example). Alternatively or in addition, substrate structure 624 comprises features of substrate structure 140 and uLED structures 130, 132, in some embodiments.

Referring now to FIG. 6B an assembly is formed at stage 601 by inserting uLED structures 621, at least partially, each into a different respective one of recess structures 611. In some embodiments, subsequent processing fabricates, couples, or otherwise provides additional circuit structures and/or optical communication devices (not shown) which are thereby configured to operate with array 620.

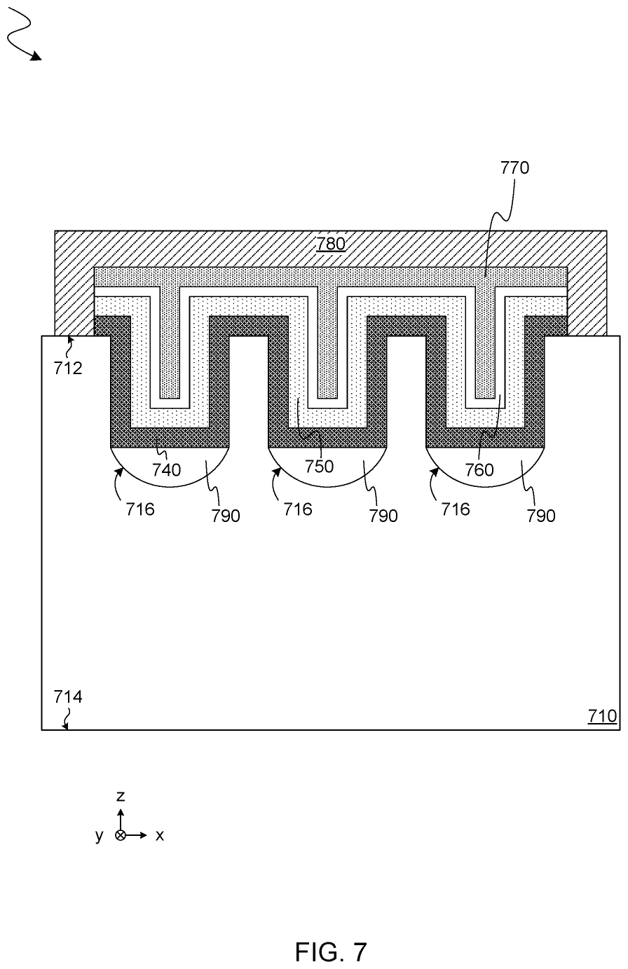

FIG. 7 shows a cross-sectional side view of a device 700 comprising an array of lensed uLED structures according to an embodiment. Device 700 illustrates features of one example embodiment wherein recess structures in a transparent substrate form, have disposed therein, or otherwise provide lenses structures which facilitate a focusing of one or more optical signals. In some embodiments, device 700 provides functionality such as that of system 100, device 300, or device 400—e.g., wherein operations of method 200 are performed with, or provide structures of, device 700.

As shown in FIG. 7, device 700 comprises a transparent substrate 710 and uLED structures which extend in respective recess structures 716 that are formed in a surface 712 of transparent substrate 710. Portions of surface 712 extends in a horizontal (x-y) plane, wherein recess structures 716 extend from said horizontal plane in a vertical (z-axis) direction toward an opposite surface 714 of transparent substrate 710. In various embodiments, transparent substrate 710 corresponds functionally to transparent substrate structure 110, or one of transparent substrates 310, 410, 610.

In the example embodiment shown, device 700 comprises at least some uLED structures which are structures of a single uLED device, wherein layers and/or other contiguous bodies of respective semiconductor materials each form respective portions of said uLED structures. For example, such contiguous bodies comprise some or all of a transparent conductor structure 740, a doped structure 750, a quantum well structure 760, and another doped structure 770 (corresponding functionally to transparent conductor structure 340, doped structure 350, quantum well structure 360, and doped structure 370, for example). An insulator structure 780 of device 700 comprises a dielectric material which provides at least partial electrical insulation between the uLED structures and other circuit structures (not shown).

To facilitate efficient optical signal communications, device 700 further comprises lens structures 790 which are each disposed in a respective one of the recess structures 716. In various embodiments, lens structures 790 promote a focusing of an optical signal which is received by (or alternatively, transmitted from) the uLED structures formed by structures 740, 750, 760, 770. In one such embodiment, lens structures 790 comprises any of various suitable transparent materials which are described herein. Although some embodiments are not limited in this regard, lens structures 790 are disposed in recess structures 716 by a pick-place operation or any of various other suitable processes—e.g., prior to a deposition which formed portions of transparent conductor structure 740 in recess structures 716 and on top of lens structures 790.

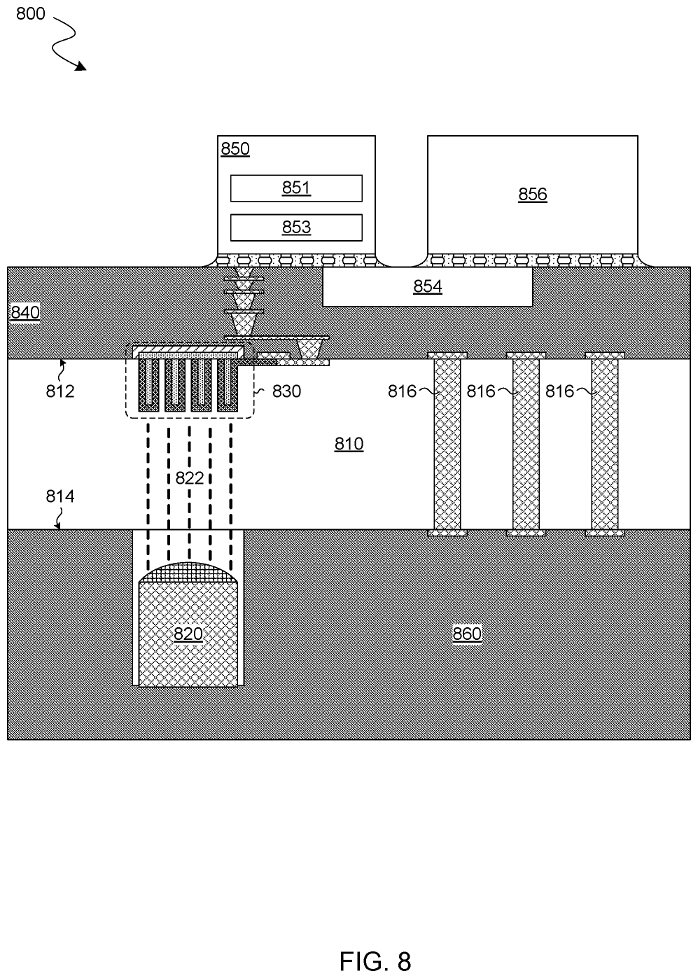

FIG. 8 shows a cross-sectional side view of a system 800 for communicating an optical signal via a transparent substrate according to an embodiment. System 800 illustrates one example embodiment wherein one or more uLED structures, which each extend in a respective recess structure of a transparent substrate, are coupled to circuitry which facilitates operation of said uLED structures as either one of an optical signal transmitter or an optical signal receiver. In some embodiments, system 800 provides functionality such as that of system 100, or of one of devices 300, 400—e.g., wherein operations of method 200 are performed with, or provide structures of, system 800.

As shown in FIG. 8, system 800 comprises substrate structures 840, 860 and a transparent substrate structure 810 which is disposed between substrate structures 840, 860. In an embodiment, one or more uLED structures (such as the illustrative uLED structures 830 shown) each extend in respective recess structure that is formed in a surface 812 of transparent substrate 810. For example, portions of surface 812 extends in a horizontal (x-y) plane, wherein recess structures extend from said horizontal plane in a vertical (z-axis) direction toward an opposite surface 814 of transparent substrate 810. In various embodiments, transparent substrate 810 corresponds functionally to transparent substrate structure 110, or one of transparent substrates 310, 410, 510, 610—e.g., wherein substrate structure 840 corresponds functionally to substrate structure 140, and wherein uLED structures 830 correspond functionally to uLED structures 130, 132.

In one embodiment, a package substrate of system 800 comprises substrate structures 840, 860 and transparent substrate structure 810, wherein transparent substrate structure 810 is a glass core of said package substrate. In an alternative embodiment, substrate structure 860 is a printed circuit board—e.g., a motherboard—or any of various other suitable devices comprising circuit structures which provide conductive pathways (not shown) to route power, ground, and/or signals, via transparent substrate structure 810, to or from circuit structures which are in or on substrate structure 840. By way of illustration and not limitation, transparent substrate structure 810 further comprises through glass via structures 816 which facilitate a provisioning of power, ground, and/or signals between substrate structures 840, 860.

In an illustrative scenario according to one embodiment, system 800 further comprises integrated circuit (IC) dies 850, 856 which, for example, each comprise a respective one of a logic die, a central processor die, a graphics processor die, a system on chip (SoC) die or the like. In one such embodiment, IC die 850 additionally or alternatively provides photonic IC (PIC) functionality, although other embodiments are not limited in this regard. IC dies 850, 856 are coupled to each other via an embedded multi-die interconnect bridge (EMIB) 854 which is integrated with (or alternatively, recessed into) substrate structure 840. With EMIB 854, substrate structure 840 provides functionality to variously facilitate electrical communication between two or more components comprising (for example) IC die 850, IC die 856, and one or more uLED devices which comprise uLED structures 830.

For example, in various embodiments, system 800 further includes (or alternatively, accommodates coupling to) an optical communication device 820 that, for example, includes some or all of the features of optical communication device 120. In an embodiment, optical communication device 820 is positioned to emit an optical signal 822 into surface 814 of transparent substrate structure 810 toward surface 812 and uLED structures 830 (or, alternatively, to receive optical signal 822 from uLED structures 830 via transparent substrate structure 810 via the surface 814 thereof). For example, optical communication device 820 includes any of various suitable optical transmitters, and/or any of various optical receivers.

In one such embodiment, IC die 850 provides functionality to selectively operate uLED structures 830, at different times, in either one of a receiver mode or a transmitter mode. For example, during a receiver mode, uLED structures 830 are operable to detect an optical signal 822 which is received via transparent substrate structure 810, and to generate a corresponding one or more electrical signals (based on optical signal 822) which are subsequently provided to IC die 850. By contrast, during a transmitter mode, uLED structures 830 are operable to generate and emit an optical signal 822 based on one or more electrical signals which is provided to uLED structures 830 by IC die 850.

In various embodiments, IC die 850 comprises receiver mode circuitry 851 which is operable to apply a first bias across a given one of uLED structures 830—e.g., wherein said first bias configures the given uLED structure to operate as an optical signal receiver (sensor). In one such embodiment, IC die 850 further comprises transmitter mode circuitry 853 which is operable to apply a second bias across the same given of uLED structure—e.g., wherein the second bias is an opposite bias, relative to the first bias—to configure the given uLED structure to operate as an optical signal transmitter (emitter). In an embodiment, the first bias and the second bias are variously applied, at different times, across doped structure 370, quantum well structure 360, and doped structure 350 of device 300 (for example).

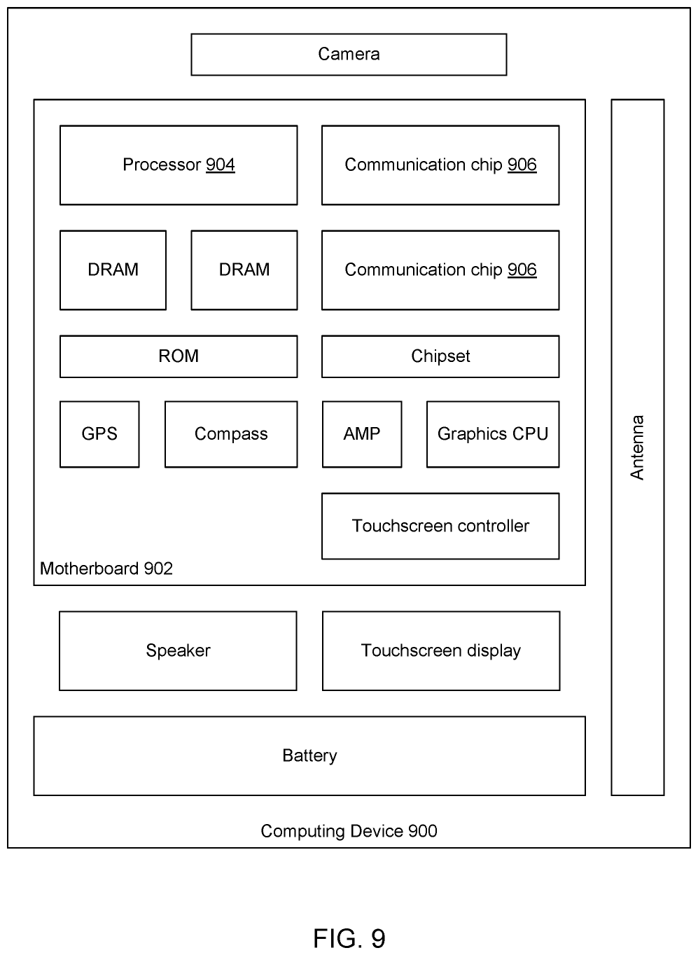

FIG. 9 illustrates a computing device 900 in accordance with one embodiment. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. The term “processor” may refer to any device or portion of a device that processes electronic data from registers and/or memory to transform that electronic data into other electronic data that may be stored in registers and/or memory. The communication chip 906 also includes an integrated circuit die packaged within the communication chip 906.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

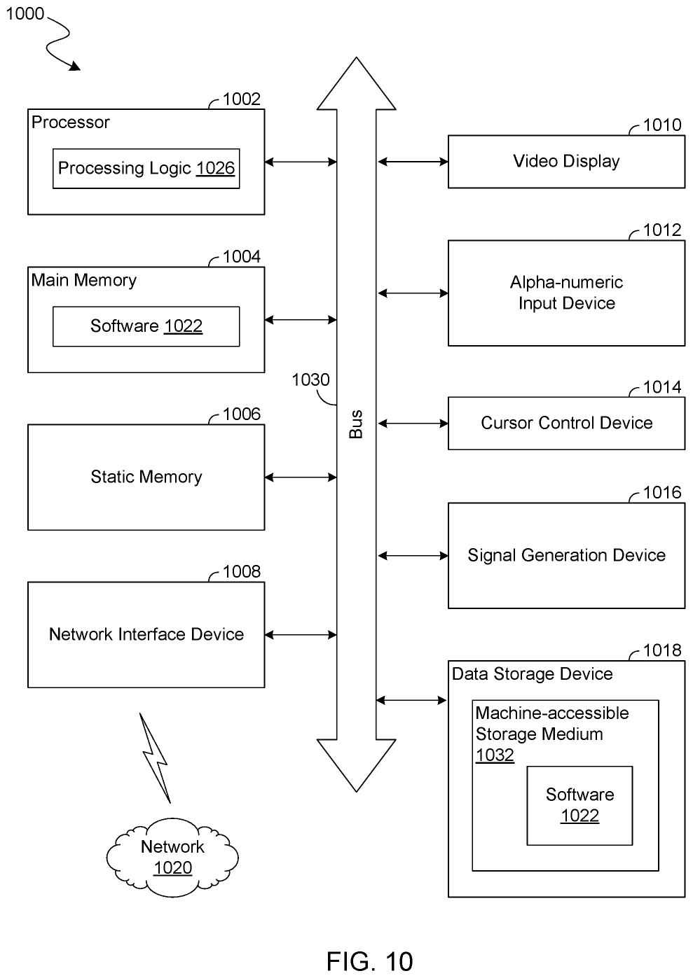

FIG. 10 illustrates a diagrammatic representation of a machine in the exemplary form of a computer system 1000 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 1000 includes a processor 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), etc.), and a secondary memory 1018 (e.g., a data storage device), which communicate with each other via a bus 1030.

Processor 1002 represents one or more general-purpose processing devices such as a microprocessor, central processing unit, or the like. More particularly, the processor 1002 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 1002 may also be one or more special-purpose processing devices such as an application specific integrated circuit (ASIC), a field programmable gate array (FPGA), a digital signal processor (DSP), network processor, or the like. Processor 1002 is configured to execute the processing logic 1026 for performing the operations described herein.

The computer system 1000 may further include a network interface device 1008. The computer system 1000 also may include a video display unit 1010 (e.g., a liquid crystal display (LCD), a light emitting diode display (LED), or a cathode ray tube (CRT)), an alphanumeric input device 1012 (e.g., a keyboard), a cursor control device 1014 (e.g., a mouse), and a signal generation device 1016 (e.g., a speaker).

The secondary memory 1018 may include a machine-accessible storage medium (or more specifically a computer-readable storage medium) 1032 on which is stored one or more sets of instructions (e.g., software 1022) embodying any one or more of the methodologies or functions described herein. The software 1022 may also reside, completely or at least partially, within the main memory 1004 and/or within the processor 1002 during execution thereof by the computer system 1000, the main memory 1004 and the processor 1002 also constituting machine-readable storage media. The software 1022 may further be transmitted or received over a network 1020 via the network interface device 1008.

While the machine-accessible storage medium 1032 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

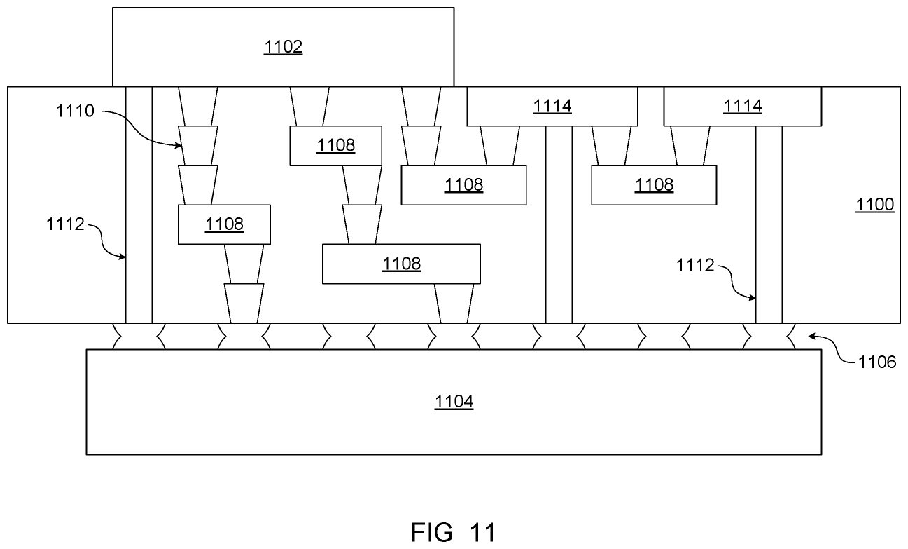

FIG. 11 illustrates an interposer 1100 that includes one or more embodiments. The interposer 1100 is an intervening substrate used to bridge a first substrate 1102 to a second substrate 1104. The first substrate 1102 may be, for instance, an integrated circuit die. The second substrate 1104 may be, for instance, a memory module, a computer motherboard, or another integrated circuit die. Generally, the purpose of an interposer 1100 is to spread a connection to a wider pitch or to reroute a connection to a different connection. For example, an interposer 1100 may couple an integrated circuit die to a ball grid array (BGA) 1106 that can subsequently be coupled to the second substrate 1104. In some embodiments, the first and second substrates 1102, 1104 are attached to opposing sides of the interposer 1100. In other embodiments, the first and second substrates 1102, 1104 are attached to the same side of the interposer 1100. And in further embodiments, three or more substrates are interconnected by way of the interposer 1100.

The interposer 1100 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 1108 and vias 1110, including but not limited to through-silicon vias (TSVs) 1112. The interposer 1100 may further include embedded devices 1114, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1100. In accordance with some embodiments, apparatuses or processes disclosed herein may be used in the fabrication of interposer 1100.

In the following description, numerous details are discussed to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a.” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first.” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front.” “back.” “top.” “bottom,” “over,” “under,” and the like in the description and in the claims, if any, are used for descriptive purposes and not necessarily for describing permanent relative positions. For example, the terms “over,” “under.” “front side.” “back side,” “top.” “bottom,” “over,” “under.” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

Techniques and architectures for communicating an optical signal via a transparent substrate are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

In one or more first embodiments, a device comprises a transparent substrate structure comprising a first surface which extends in a first plane at a first side of the transparent substrate structure, wherein the first surface forms a recess structure that extends from the first plane toward a second side of the transparent substrate structure, and a micro light emitting diode (uLED) structure disposed on the first surface, wherein the uLED structure extends in the recess structure, wherein the uLED structure is oriented to communicate an optical signal which is propagated through the transparent substrate structure.

In one or more second embodiments, further to the first embodiment, the uLED structure comprises a first doped portion, a second doped portion, and quantum well structure which extends between the first doped portion and the second doped portion, wherein the first doped portion, the second doped portion, and the quantum well structure each extend at least partially into the recess structure.

In one or more third embodiments, further to the second embodiment, the first doped portion comprises a n-type doped material comprising gallium and nitrogen, the second doped portion comprises a p-type doped material comprising gallium and nitrogen, and the quantum well structure comprises indium, gallium and nitrogen.

In one or more fourth embodiments, further to the second embodiment, the uLED structure further comprises a transparent electrode structure which extends at least partially into the recess structure, wherein the transparent electrode structure extends around the first doped portion, the second doped portion, and the quantum well structure.

In one or more fifth embodiments, further to the first embodiment or the second embodiment, the transparent substrate structure is a core of a package substrate.

In one or more sixth embodiments, further to the first embodiment or the second embodiment, the device further comprises a conductive interconnect structure at the first surface, wherein the conductive interconnect structure is coupled to communicate an electrical signal with the uLED structure, wherein one of the electrical signal or the optical signal is to be based on the other of the electrical signal or the optical signal.

In one or more seventh embodiments, further to the first embodiment or the second embodiment, a thickness of the transparent substrate substructure is in a range of 50 micrometers (um) to 2000 um, and a depth of the recess structure is in a range of 10 nanometers (nm) to 10000 nm.

In one or more eighth embodiments, further to the first embodiment or the second embodiment, the uLED structure is a first uLED structure, the recess structure is a first recess structure, the first surface further forms a second recess structure that extends from the first plane toward the second surface, and the device further comprises a second uLED structure disposed on the first surface, wherein the second uLED structure extends in the recess structure.

In one or more ninth embodiments, further to the eighth embodiment, a first contiguous body of a first doped material forms respective first doped portions of the first uLED structure and the second uLED structure, a second contiguous body of a second doped material forms respective second doped portions of the first uLED structure and the second uLED structure, and a layer of an undoped material forms respective quantum well structures of the first uLED structure and the second uLED structure.

In one or more tenth embodiments, further to the eighth embodiment, the device comprises an array of uLED structures comprising the first uLED structure and the second uLED structure, wherein an arrangement of uLED structures in the array conforms to an arrangement of hexagonal tiles in a regular tessellation pattern.

In one or more eleventh embodiments, a method comprises forming a recess structure in a first surface of a transparent substrate structure, wherein the first surface extends in a first plane at a first side of the transparent substrate structure, and wherein the recess structure extends from the first plane toward a second side of the transparent substrate structure, forming a micro light emitting diode (uLED) structure on the first surface, wherein the uLED structure extends in the recess structure, wherein the uLED structure is oriented to communicate an optical signal which is propagated through the transparent substrate structure, forming a conductive interconnect structure at the first surface, wherein the conductive interconnect structure is coupled to communicate an electrical signal with the uLED structure, wherein one of the electrical signal or the optical signal is to be based on the other of the electrical signal or the optical signal.

In one or more twelfth embodiments, further to the eleventh embodiment, the uLED structure comprises forming a first doped portion, a second doped portion, and quantum well structure which extends between the first doped portion and the second doped portion, and after the uLED structure is formed at the first surface, the first doped portion, the second doped portion, and the quantum well structure each extend at least partially into the recess structure.

In one or more thirteenth embodiments, further to the twelfth embodiment, forming the uLED structure on the first surface comprises performing a first deposition of a first doped material into the recess structure, after the first deposition, performing a second deposition of an undoped material into the recess structure, and after the second deposition, performing a third deposition of a second doped material into the recess structure.

In one or more fourteenth embodiments, further to the twelfth embodiment, forming the uLED structure on the first surface comprises performing an assembly which inserts at least a portion of the uLED structure into the recess structure.

In one or more fifteenth embodiments, further to the eleventh embodiment or the twelfth embodiment, the transparent substrate structure is a core of a package substrate.

In one or more sixteenth embodiments, further to the eleventh embodiment or the twelfth embodiment, a thickness of the transparent substrate substructure is in a range of 50 micrometers (um) to 2000 um, and a depth of the recess structure is in a range of 10 nanometers (nm) to 10000 nm.

In one or more seventeenth embodiments, further to the eleventh embodiment or the twelfth embodiment, the uLED structure is a first uLED structure, the recess structure is a first recess structure, the method further comprises forming a second recess structure in the first surface, wherein the second recess structure extends from the first plane toward the second side, and forming a second uLED structure on the first surface, wherein the second uLED structure extends in the second recess structure.

In one or more eighteenth embodiments, further to the seventeenth embodiment, a first contiguous body of a first doped material forms respective first doped portions of the first uLED structure and the second uLED structure, a second contiguous body of a second doped material forms respective second doped portions of the first uLED structure and the second uLED structure, and a layer of an undoped material forms respective quantum well structures of the first uLED structure and the second uLED structure.

In one or more nineteenth embodiments, further to the seventeenth embodiment, forming the uLED structure comprises forming an array of uLED structures comprising the first uLED structure and the second uLED structure, wherein an arrangement of uLED structures in the array conforms to an arrangement of hexagonal tiles in a regular tessellation pattern.

In one or more twentieth embodiments, a system comprises a package substrate comprising a transparent core comprising a first surface which extends in a first plane at a first side of the transparent core, wherein the first surface forms a recess structure that extends from the first plane toward a second side of the transparent core, and a micro light emitting diode (uLED) structure disposed on the first surface, wherein the uLED structure extends in the recess structure, wherein the uLED structure is oriented to communicate an optical signal which is propagated through the transparent core, an optical communication device coupled to the package substrate, optical communication device to communicate the optical signal with the uLED structure via the transparent core.

In one or more twenty-first embodiments, further to the twentieth embodiment, the uLED structure comprises a first doped portion, a second doped portion, and quantum well structure which extends between the first doped portion and the second doped portion, wherein the first doped portion, the second doped portion, and the quantum well structure each extend at least partially into the recess structure.

In one or more twenty-second embodiments, further to the twenty-first embodiment, the first doped portion comprises a n-type doped material comprising gallium and nitrogen, the second doped portion comprises a p-type doped material comprising gallium and nitrogen, and the quantum well structure comprises indium, gallium and nitrogen.

In one or more twenty-third embodiments, further to the twenty-first embodiment, the uLED structure further comprises a transparent electrode structure which extends at least partially into the recess structure, wherein the transparent electrode structure extends around the first doped portion, the second doped portion, and the quantum well structure.

In one or more twenty-fourth embodiments, further to the twentieth embodiment or the twenty-first embodiment, the package substrate further comprises a conductive interconnect structure at the first surface, wherein the conductive interconnect structure is coupled to communicate an electrical signal with the uLED structure, wherein one of the electrical signal or the optical signal is to be based on the other of the electrical signal or the optical signal.

In one or more twenty-fifth embodiments, further to the twentieth embodiment or the twenty-first embodiment, a thickness of the transparent core is in a range of 50 micrometers (um) to 2000 um, and a depth of the recess structure is in a range of 10 nanometers (nm) to 10000 nm.

In one or more twenty-sixth embodiments, further to the twentieth embodiment or the twenty-first embodiment, the uLED structure is a first uLED structure, the recess structure is a first recess structure, the first surface further forms a second recess structure that extends from the first plane toward the second surface, and the package substrate further comprises a second uLED structure disposed on the first surface, wherein the second uLED structure extends in the recess structure.

In one or more twenty-seventh embodiments, further to the twenty-sixth embodiment, a first contiguous body of a first doped material forms respective first doped portions of the first uLED structure and the second uLED structure, a second contiguous body of a second doped material forms respective second doped portions of the first uLED structure and the second uLED structure, and a layer of an undoped material forms respective quantum well structures of the first uLED structure and the second uLED structure.

In one or more twenty-eighth embodiments, further to the twenty-sixth embodiment, the package substrate comprises an array of uLED structures comprising the first uLED structure and the second uLED structure, wherein an arrangement of uLED structures in the array conforms to an arrangement of hexagonal tiles in a regular tessellation pattern.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A device comprising:
a transparent substrate structure comprising a first surface which extends in a first plane at a first side of the transparent substrate structure, wherein the first surface forms a recess structure that extends from the first plane toward a second side of the transparent substrate structure; and
a micro light emitting diode (uLED) structure disposed on the first surface, wherein the uLED structure extends in the recess structure, wherein the uLED structure is oriented to communicate an optical signal which is propagated through the transparent substrate structure.

2. The device of claim 1, wherein the uLED structure comprises a first doped portion, a second doped portion, and quantum well structure which extends between the first doped portion and the second doped portion, wherein the first doped portion, the second doped portion, and the quantum well structure each extend at least partially into the recess structure.

3. The device of claim 2, wherein:
the first doped portion comprises a n-type doped material comprising gallium and nitrogen;
the second doped portion comprises a p-type doped material comprising gallium and nitrogen; and
the quantum well structure comprises indium, gallium and nitrogen.

4. The device of claim 2, wherein the uLED structure further comprises a transparent electrode structure which extends at least partially into the recess structure, wherein the transparent electrode structure extends around the first doped portion, the second doped portion, and the quantum well structure.

5. The device of claim 1, wherein the transparent substrate structure is a core of a package substrate.

6. The device of claim 1, further comprising a conductive interconnect structure at the first surface, wherein the conductive interconnect structure is coupled to communicate an electrical signal with the uLED structure, wherein one of the electrical signal or the optical signal is to be based on the other of the electrical signal or the optical signal.

7. The device of claim 1, wherein:
the uLED structure is a first uLED structure;
the recess structure is a first recess structure;
the first surface further forms a second recess structure that extends from the first plane toward the second surface; and
the device further comprises a second uLED structure disposed on the first surface, wherein the second uLED structure extends in the recess structure.

8. The device of claim 7, wherein:
a first contiguous body of a first doped material forms respective first doped portions of the first uLED structure and the second uLED structure;
a second contiguous body of a second doped material forms respective second doped portions of the first uLED structure and the second uLED structure; and
a layer of an undoped material forms respective quantum well structures of the first uLED structure and the second uLED structure.

9. The device of claim 7, wherein the device comprises an array of uLED structures comprising the first uLED structure and the second uLED structure, wherein an arrangement of uLED structures in the array conforms to an arrangement of hexagonal tiles in a regular tessellation pattern.

10. A method comprising:
forming a recess structure in a first surface of a transparent substrate structure, wherein the first surface extends in a first plane at a first side of the transparent substrate structure, and wherein the recess structure extends from the first plane toward a second side of the transparent substrate structure;
forming a micro light emitting diode (uLED) structure on the first surface, wherein the uLED structure extends in the recess structure, wherein the uLED structure is oriented to communicate an optical signal which is propagated through the transparent substrate structure;
forming a conductive interconnect structure at the first surface, wherein the conductive interconnect structure is coupled to communicate an electrical signal with the uLED structure, wherein one of the electrical signal or the optical signal is to be based on the other of the electrical signal or the optical signal.

11. The method of claim 10, wherein:
the uLED structure comprises forming a first doped portion, a second doped portion, and quantum well structure which extends between the first doped portion and the second doped portion; and
after the uLED structure is formed at the first surface, the first doped portion, the second doped portion, and the quantum well structure each extend at least partially into the recess structure.

12. The method of claim 11, wherein forming the uLED structure on the first surface comprises:
performing a first deposition of a first doped material into the recess structure;
after the first deposition, performing a second deposition of an undoped material into the recess structure; and
after the second deposition, performing a third deposition of a second doped material into the recess structure.

13. The method of claim 11, wherein forming the uLED structure on the first surface comprises performing an assembly which inserts at least a portion of the uLED structure into the recess structure.

14. The method of claim 10, wherein the transparent substrate structure is a core of a package substrate.

15. The method of claim 10, wherein:
the uLED structure is a first uLED structure;
the recess structure is a first recess structure;
the method further comprises:
forming a second recess structure in the first surface, wherein the second recess structure extends from the first plane toward the second side; and
forming a second uLED structure on the first surface, wherein the second uLED structure extends in the second recess structure.

16. A system comprising:
a package substrate comprising:
a transparent core comprising a first surface which extends in a first plane at a first side of the transparent core, wherein the first surface forms a recess structure that extends from the first plane toward a second side of the transparent core; and
a micro light emitting diode (uLED) structure disposed on the first surface, wherein the uLED structure extends in the recess structure, wherein the uLED structure is oriented to communicate an optical signal which is propagated through the transparent core;
an optical communication device coupled to the package substrate, optical communication device to communicate the optical signal with the uLED structure via the transparent core.

17. The system of claim 16, wherein the uLED structure comprises a first doped portion, a second doped portion, and quantum well structure which extends between the first doped portion and the second doped portion, wherein the first doped portion, the second doped portion, and the quantum well structure each extend at least partially into the recess structure.

18. The system of claim 17, wherein:
the first doped portion comprises a n-type doped material comprising gallium and nitrogen;
the second doped portion comprises a p-type doped material comprising gallium and nitrogen; and
the quantum well structure comprises indium, gallium and nitrogen.

19. The system of claim 17, wherein the uLED structure further comprises a transparent electrode structure which extends at least partially into the recess structure, wherein the transparent electrode structure extends around the first doped portion, the second doped portion, and the quantum well structure.

20. The system of claim 16, wherein the package substrate further comprises a conductive interconnect structure at the first surface, wherein the conductive interconnect structure is coupled to communicate an electrical signal with the uLED structure, wherein one of the electrical signal or the optical signal is to be based on the other of the electrical signal or the optical signal.
